(19) United States
(12) Patent Application Publication
(10) Pub. No.: US 2026/0037681 A1
(43) Pub. Date: Feb. 5, 2026

(54) METHOD OF REPRESENTING A DENTAL OBJECT USING BINARY SPACE PARTITIONING, METHOD OF REPRESENTING AN OBJECT USING BINARY SPACE PARTITIONING AND COMPUTER READABLE MEDIUM HAVING PROGRAM FOR PERFORMING THE METHOD

(71) Applicant: IMAGOWORKS INC., Seoul (KR)

(72) Inventors: Gyujin CHOI, Seoul (KR); Jungho PARK, Seoul (KR)

(73) Assignee: IMAGOWORKS INC., Seoul (KR)

(21) Appl. No.: 19/277,651

(22) Filed: Jul. 23, 2025

(30) Foreign Application Priority Data
Jul. 31, 2024 (KR) 10-2024-0102095
Aug. 14, 2024 (WO) PCT/KR2024/012104

(51) Int. Cl. G06F 30/12

(52) U.S. Cl. CPC G06F 30/12

(57) ABSTRACT

A method of representing a dental object using a binary space partitioning for performing a binary space partitioning according to the present inventive concept, the method includes generating internal trees for partitioning a space including the dental object represented as a polygon mesh, and generating leaf trees for representing a shape of the dental object in spaces generated based on the internal trees. Each of the internal trees and the leaf trees includes internal nodes and leaf nodes.

### PRIORITY STATEMENT

This application claims priority under 35 U.S.C. § 119 to Korean Patent Application No. 10-2024-0102095, filed on Jul. 31, 2024 in the Korean Intellectual Property Office (KIPO) and International Patent Application No. PCT/KR2024/012104 filed on Aug. 14, 2024, the contents of which are herein incorporated by reference in their entireties.

### BACKGROUND

### 1. Technical Field

Embodiments relate to a method of representing a dental object using binary space partitioning, a method of representing an object using a binary space partitioning and computer readable medium having program for performing the method. More particularly, embodiments relate to a dental object using a binary space partitioning, a method of representing an object using a binary space partitioning and computer readable medium having program for performing the method for parallelizing an operation.

### 2. Description of the Related Art

In a field of a computer graphic, it may be important to draw a space quickly and accurately. The space may be represented by a binary space partitioning. The binary space partitioning is a method of recursively partitioning a Euclidean space into a hyperplane. For example, when the Euclidean space is two-dimensional, the Euclidean space may be partitioned into a first-dimensional straight line. For example, when the Euclidean space is three-dimensional, the Euclidean space may be partitioned into a three-dimensional plane.

However, the binary space partitioning may take a very long time to calculate for input data having a complex shape or a large number of geometric elements, and may require a lot of memory space.

### SUMMARY

Embodiments provide a method of representing a dental object using a binary space partitioning for performing a binary space partitioning in parallel to improve a computation speed, requiring less memory space, and effectively parallelizing computation.

Embodiments provide a method of representing an object using a binary space partitioning for performing a binary space partitioning in parallel to improve a computation speed, requiring less memory space, and effectively parallelizing computation.

Embodiments provide a computer readable medium having program for executing the method of representing the dental object using the binary space partitioning for performing the binary space partitioning and the method of representing the object using a binary space partitioning for performing the binary space partitioning

In an example method of representing a dental object using a binary space partitioning for performing a binary space partitioning according to the present inventive concept, the method includes generating internal trees for partitioning a space including the dental object represented as a polygon mesh, and generating leaf trees for representing a shape of the dental object in spaces generated based on the internal trees. Each of the internal trees and the leaf trees includes internal nodes and leaf nodes.

In an embodiment, when the space is partitioned, a median splitting technique may be performed such that a number of faces of the polygon mesh is halved.

In an embodiment, the internal trees may constitute first to N-th (wherein N is a natural number greater than or equal to 1) internal tree layers, and internal trees included in the second internal tree layer may be constituted based on leaf nodes of an internal tree included in the first internal tree layer.

In an embodiment, a depth of nodes included in each of the internal trees may be less than or equal to a maximum partial tree depth.

In an embodiment, the leaf trees may constitute one leaf tree layer.

In an embodiment, the leaf trees may be constituted based on the leaf nodes of internal trees included in the N-th internal tree layer.

In an embodiment, a depth of the nodes included in the internal trees and the leaf trees may be less than or equal to a maximum augmented tree depth.

In an embodiment, a number of polygon meshes included in each of the spaces generated based on the internal trees may be less than or equal to a maximum number of leaf tree space faces.

In an embodiment, parent nodes and child nodes may be constituted based on the internal nodes and the leaf nodes, and each of the parent nodes has two child nodes.

In an embodiment, the internal trees and the leaf trees may constitute parent trees and child trees, and each of the parent trees may have at least two child trees.

In an embodiment, the internal trees may be generated by a working stealing algorithm.

In an embodiment, the working stealing algorithm may be performed by workers, and the workers may perform a work on at least one internal tree.

In an embodiment, each of the workers may be configured to perform the work in a working stealing queue of each of the workers, and a worker which has completed one work may be configured to steal other work to perform the other work.

In an embodiment, the polygon mesh may be a polygonal face.

In an embodiment, when the space is two-dimensional, the space may be partitioned by a first-dimensional straight line.

In an embodiment, when the space is three-dimensional, the space may be partitioned by a two-dimensional plane.

In an example method of representing an object using a binary space partitioning for performing a binary space partitioning according to the present inventive concept, the method includes generating internal trees for partitioning a space including the object represented as a polygon mesh, and generating leaf trees for representing a shape of the object in spaces generated based on the internal trees. Each of the internal trees and the leaf trees includes internal nodes and leaf nodes.

In an embodiment, a depth of nodes included in each of the internal trees may be less than or equal to a maximum partial tree depth.

In an embodiment, a number of polygon meshes included in each of the spaces generated based on the internal trees may be less than or equal to a maximum number of leaf tree space faces.

In an embodiment, a program for executing the method of representing the dental object using the binary space partitioning and the method of representing the object using the binary space partitioning on a computer may be stored in a computer readable medium.

According to the method of representing the dental object using the binary space partitioning, the method of representing the object using the binary space partitioning, and the computer readable medium having the program, the space including the dental object (or the object) including the polygon mesh may include a number of polygons included in each of the spaces generated based on the internal trees by internal trees uniformly. Therefore, since an operation performed in each of the spaces generated based on the internal trees may be uniformly performed, the operation may be efficiently parallelized.

In addition, the internal trees may be generated by the working stealing algorithm. Therefore, the workers may efficiently perform the work.

### BRIEF DESCRIPTION OF THE DRAWINGS

The above and other features and advantages of the present inventive concept will become more apparent by describing in detailed embodiments thereof with reference to the accompanying drawings, in which:

FIG. 1 is a diagram explaining a concept of a binary space partitioning;

FIG. 2 is a flowchart showing a method of representing an object using a binary space partitioning according to an embodiment of the present inventive concept;

FIG. 3 and FIG. 4 are diagrams explaining internal trees and leaf trees of FIG. 2;

FIG. 5 and FIG. 6 are diagrams explaining spaces generated based on internal nodes;

FIG. 7 is a diagram explaining a working stealing algorithm; and

FIG. 8 and FIG. 9 are diagrams illustrating a dental object on which a method of representing a dental object using a binary space partitioning according to an embodiment of the present inventive concept is performed.

### DETAILED DESCRIPTION OF THE EMBODIMENTS

The present inventive concept now will be described more fully hereinafter with reference to the accompanying drawings, in which embodiments of the present inventive concept are shown. The present inventive concept may, however, be embodied in many different forms and should not be construed as limited to the embodiments set forth herein.

Rather, these embodiments are provided so that this disclosure will be thorough and complete, and will fully convey the scope of the present inventive concept to those skilled in the art. Like reference numerals refer to like elements throughout.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the inventive concept as used herein.

Hereinafter, the present inventive concept will be explained in detail with reference to the accompanying drawings.

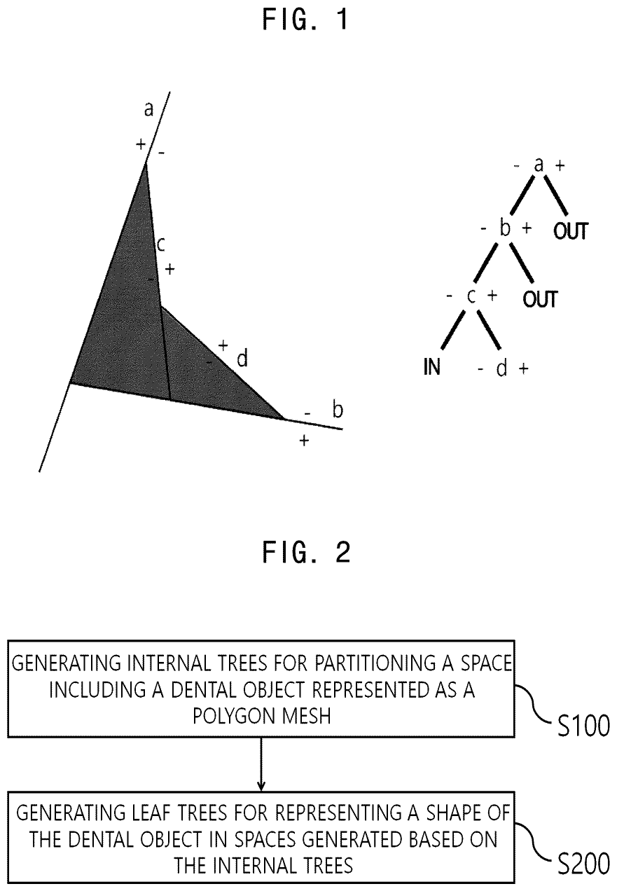

FIG. 1 is a diagram explaining a concept of a binary space partitioning.

Referring to FIG. 1, a space may be represented by a binary space partitioning. The binary space partitioning is a method of recursively partitioning a Euclidean space into a hyperplane. For example, when the Euclidean space is two-dimensional, the Euclidean space may be partitioned into a first-dimensional straight line. For example, when the Euclidean space is three-dimensional, the Euclidean space may be partitioned into a three-dimensional plane. FIG. 1 is an example of partitioning the two-dimensional space. A left diagram of FIG. 1 shows an example of partitioning the two-dimensional space into the first-dimensional straight line, and a right diagram of FIG. 1 shows the example as a binary space partitioning tree.

Referring to the left diagram of FIG. 1, the two-dimensional space may be partitioned into +space and −space based on a “a” straight line. Referring to the right diagram of FIG. 1, the “a” straight line may correspond to a “a” node, the +space of the “a” straight line may correspond to OUT of the “a” node, and the −space of the “a” straight line may correspond to IN of the “a” node.

Referring to the left diagram of FIG. 1, the −space of the “a” straight line may be partitioned into +space and −space based on a “b” straight line. Referring to the right diagram of FIG. 1, the “b” straight line may correspond to a “b” node, the +space may correspond to OUT, and the −space may correspond to IN.

Referring to the left diagram of FIG. 1, the −space of the “b” straight line may be partitioned into +space and −space based on a “c” straight line. Referring to the right diagram of FIG. 1, the “c” straight line may correspond to a “c” node, the +space may correspond to OUT, and the −space may correspond to IN.

Referring to the left diagram of FIG. 1, the −space of the “c” straight line may be partitioned into +space and −space based on a “d” straight line. Referring to the right diagram of FIG. 1, the “d” straight line may correspond to a “d” node, the +space may correspond to OUT, and the −space may correspond to IN.

The space may include an object represented by a polygon mesh. The polygon mesh may be a polygonal face. For example, the polygon mesh may be a triangular face or a square face. The object may be represented using the binary space partitioning. A method of representing an object using binary space partitioning according to an embodiment of the present inventive concept provides a binary space partitioning for effectively parallelizing an operation.

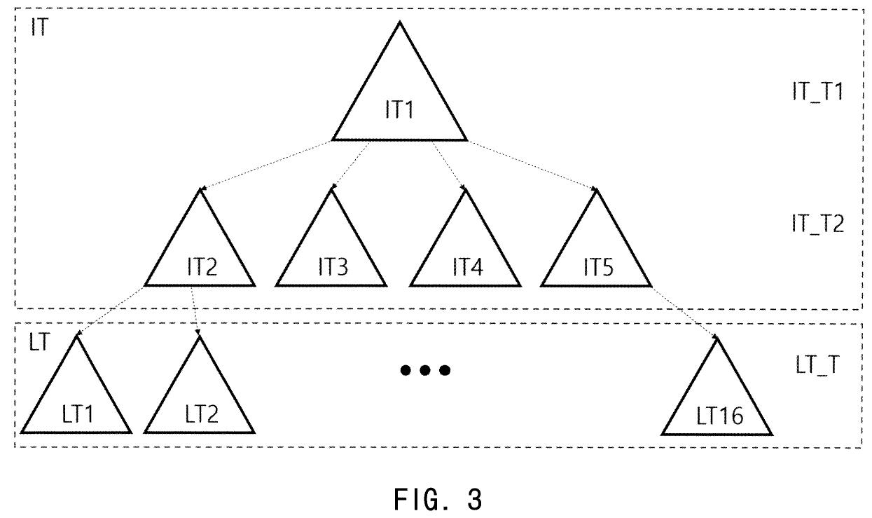

FIG. 2 is a flowchart showing a method of representing an object using a binary space partitioning according to an embodiment of the present inventive concept.

Referring to FIG. 2, the method of representing an object using a binary space partitioning according to an embodiment of the present inventive concept may include generating internal trees for partitioning a space including a dental object represented as a polygon mesh S100, and generating leaf trees for representing a shape of the dental object in spaces generated based on the internal trees S200. Each of the internal trees and the leaf trees may include internal nodes and leaf nodes.

The method of representing the dental object using the binary space partitioning according to an embodiment of the present inventive concept may be performed by a computing device.

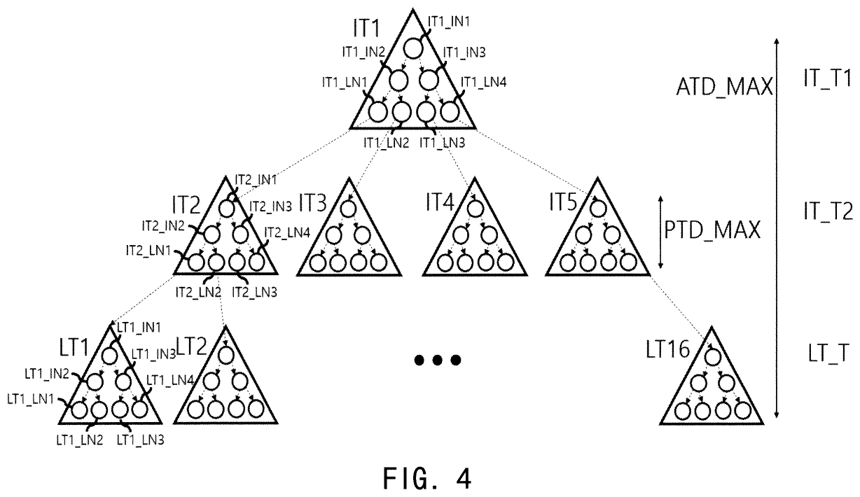

FIG. 3 and FIG. 4 are diagrams explaining internal trees IT and leaf trees LT of FIG. 2.

Referring to FIG. 3, the method of representing a dental object using binary space partitioning according to an embodiment of the present inventive concept may include generating the internal trees IT for partitioning the space including the dental object represented as the polygon mesh S100.

Generating the internal trees IT for partitioning the space including the dental object represented as the polygon mesh S100 may be performed until a number of polygon meshes included in each of the spaces generated based on the internal trees IT becomes less than or equal to a maximum number of leaf tree space faces. Accordingly, since an operation performed in each of the spaces generated based on the internal trees IT may be uniform, the operation may be effectively parallelized. The generated internal trees IT may form first to N-th (Here, N is a natural number greater than or equal to 1) internal tree layers.

For example, second to fifth internal trees IT2 to IT5 may be generated based on a first internal tree IT1. In this case, the first internal tree IT1 may be a parent tree, and the second to fifth internal trees IT2 to IT5 may be child trees. Here, the first to fifth internal trees IT1 to IT5 may constitute (or form) a first internal tree layer IT_T1 and a second internal tree layer IT_T2. The first internal tree IT1 may constitute (or form) the first internal tree layer IT_T1, and the second to fifth internal trees IT2 to IT5 may constitute (or form) the second internal tree layer IT_T2.

The method of representing a dental object using the binary space partitioning according to an embodiment of the present inventive concept may include generating the leaf trees LT for representing the shape of the dental object in the spaces generated based on the internal trees IT S200. The generated leaf trees LT may constitute (or form) one leaf tree layer LT_T.

For example, first to sixteenth leaf trees LT1 to LT16 may be generated based on the second to fifth internal trees IT2 to IT5. In this case, the second to fifth internal trees IT2 to IT5 may be parent trees, and the first to sixteenth leaf trees LT1 to LT16 may be child trees. Here, the first to sixteenth leaf trees LT1 to LT16 may constitute (or form) the leaf tree layer LT_T.

As such, the internal trees IT and the leaf trees LT may constitute (or form) parent trees and child trees, and each of the parent trees may have at least two child trees. Referring to FIG. 4, the internal trees IT and the leaf trees LT may constitute (or form)

an augmented binary space partitioning tree together. Each of the internal trees IT and the leaf trees LT may constitute (or form) a binary space partitioning tree. Therefore, each of the internal trees IT may include internal nodes and leaf nodes. As described in FIG. 1, each of the internal nodes and the leaf nodes may mean partitioning a space. The space partitioning may be performed such that a number of faces of the polygon mesh is halved. For example, a median splitting technique may be performed in the space partitioning.

A depth of nodes included in each of the internal trees IT may be less than or equal to a maximum partial tree depth PTD_MAX. Therefore, when the depth of the nodes included in each of the internal trees IT becomes the maximum partial tree depth PTD_MAX, internal trees or leaf trees corresponding to a child tree may be newly generated. Accordingly, the operation performed in each of the spaces generated based on the internal trees IT may be uniform.

Even if the operation performed in each of the spaces generated based on the internal trees IT is uniform, if an overall operation amount is too large, the operation speed may decrease.

To prevent this, a depth of nodes included in the augmented binary space partitioning tree (i.e., the internal trees IT and the leaf trees LT) may be less than or equal to a maximum augmented tree depth ATD_MAX. Accordingly, the overall operation amount may decrease.

For example, the maximum partial tree depth PTD_MAX may be 3, a first internal tree IT1 may constitute (or form) the first internal tree layer IT_T1, and the first internal tree IT1 may include a first internal node IT1_IN1. A second internal node IT1_IN2 and a third internal node IT1_IN3 may be generated based on the first internal node IT1_IN1. In this case, the first internal node IT1_IN1 may be a parent node, and the second internal node IT1_IN2 and the third internal node IT1_IN3 may be child nodes. A first leaf node IT1_LN1 and a second leaf node IT1_LN2 may be generated based on the second internal node IT1_IN2. In this case, the second internal node IT1_IN2 may be a parent node, and the first leaf node IT1_LN1 and the second leaf node IT1_LN2 may be child nodes. A third leaf node IT1_LN3 and a fourth leaf node IT1_LN4 may be generated based on the third internal node IT1_IN3. In this case, the third internal node IT1_IN3 may be a parent node, and the third leaf node IT1 LN3 and the fourth leaf node IT1_LN4 may be child nodes.

Based on the first internal tree IT1, child trees may be generated. Since a number of leaf nodes IT1_LN1, IT1_LN2, IT1_LN3, IT1_LN4 of the first internal tree IT1 is 4, a number of the child trees of the first internal tree ITI may be 4. That is, the second to fifth internal trees IT2 to IT5 may be generated based on the first internal tree IT1. The second to fifth internal trees IT2 to IT5 may constitute (or form) the second internal tree layer IT_T2. For example, the second internal tree IT2 may include a first internal node IT2 IN1. A

second internal node IT2_IN2 and a third internal node IT2_IN3 may be generated based on the first internal node IT2_IN1. In this case, the first internal node IT2_IN1 may be a parent node, and the second internal node IT2_IN2 and the third internal node IT2_IN3 may be child nodes. A first leaf node IT2_LN1 and a second leaf node IT2_LN2 may be generated based on the second internal node IT2_IN2. In this case, the second internal node IT2_IN2 may be a parent node, and the first leaf node IT2_LN1 and the second leaf node IT2_LN2 may be child nodes. A third leaf node IT2_LN3 and a fourth leaf node IT2_LN4 may be generated based on the third internal node IT2 IN3. In this case, the third internal node IT2_IN3 may be a parent node, and the third leaf node IT2_LN3 and the fourth leaf node IT2_LN4 may be child nodes.

As described above, generating the internal trees IT for partitioning the space including the dental object represented as the polygon mesh S100 may be performed until a number of polygon meshes included in each of the spaces generated based on the internal trees IT becomes less than or equal to a maximum number of leaf tree space faces. Therefore, the spaces partitioned by each of the first to fourth leaf nodes IT2_LN1 to IT2_LN4 of the second internal tree IT2 may be less than or equal to the maximum number of the leaf tree space faces.

Based on the second to fifth internal trees IT2 to IT5, child trees may be generated. When a number of leaf nodes of the second to fifth internal trees IT2 to IT5 is 16, a number of child trees of the second to fifth internal trees IT2 to IT5 may be 16. That is, first to sixteenth leaf trees LT1 to LT16 may be generated based on the second to fifth internal trees IT2 to IT5. The first to sixteenth leaf trees LT1 to LT16 may constitute (or form) a leaf tree layer LT_T.

For example, the first leaf tree LT1 may include a first internal node LT1_IN1. A second internal node LT1_IN2 and a third internal node LT1_IN3 may be generated based on the first internal node LT1_IN1. In this case, the first internal node LT1_IN1 may be a parent node, and the second internal node LT1_IN2 and the third internal node LT1_IN3 may be child nodes. A first leaf node LT1_LN1 and a second leaf node LT1_LN2 may be generated based on the second internal node LT1_IN2. In this case, the second internal node LT1_IN2 may be a parent node, and the first leaf node LT1_LN1 and the second leaf node LT1_LN2 may be child nodes. A third leaf node LT1 LN3 and a fourth leaf node LT1_LN4 may be generated based on the third internal node LT1_IN3. In this case, the third internal node LT1_IN3 may be a parent node, and the third leaf node LT1_LN3 and the fourth leaf node LT1_LN4 may be child nodes.

As such, the internal nodes and the leaf nodes may constitute (or form) parent nodes and child nodes, and each of the parent nodes may have two child trees.

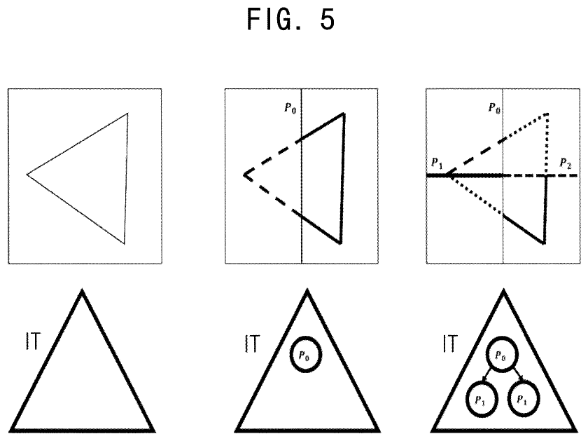

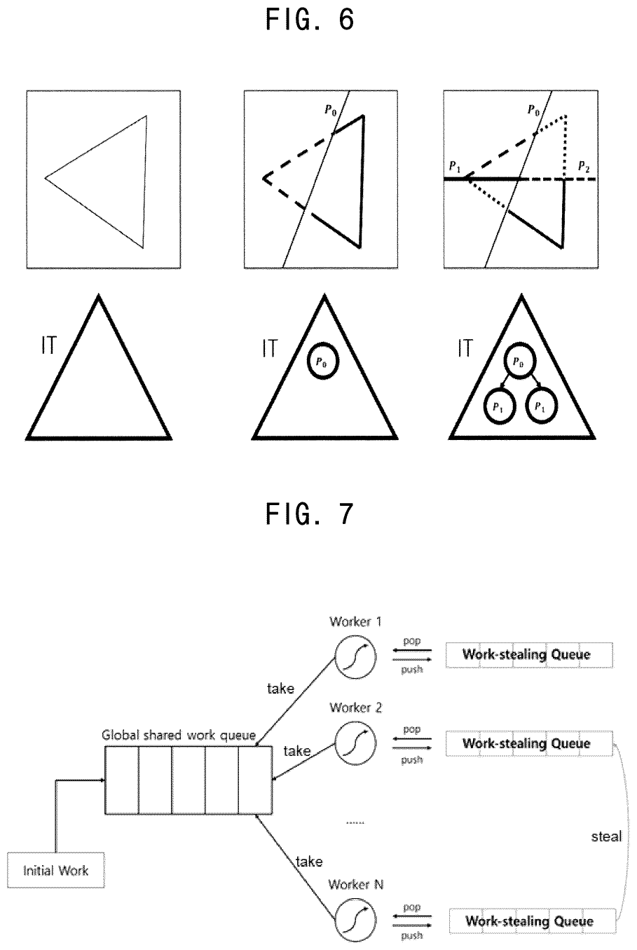

FIG. 5 and FIG. 6 are diagrams explaining spaces generated based on internal nodes.

Referring to FIG. 5 and FIG. 6, a space may include an object. The space may be a two-dimensional space, and the two-dimensional space may be partitioned into a first-dimensional straight line, and a shape of the object may be a triangle. The two-dimensional space may be partitioned into a P₀ straight line. The P₀ straight line may correspond to a P₀ node. A space on one side of the P₀ straight line may be partitioned into a P₁ straight line. The P₁ straight line may correspond to a P₁ node. A space on the other side of the P₀ line may be partitioned into a P₂ line. The P₂ line may correspond to the P₂ node.

As shown in FIGS. 5 and 6, in generated spaces, the shape of the object may be partitioned uniformly. Therefore, an operation performed in each of the generated spaces may be uniformly performed, and an operation speed may be improved.

FIG. 7 is a diagram explaining a working stealing algorithm.

Referring to FIG. 7, the internal trees IT may be generated by a working stealing algorithm. The working stealing algorithm may be performed by workers. A first work may be assigned to a global shared work queue. The first work may be implemented as an array, a queue, a deque, etc. In this case, in order to satisfy a parallel stability of a work provided to the workers, a data structure implementation which guarantees the parallel stability may be used, or a time at which a take operation of the workers is executed may be designated as a critical zone.

The first work may include at least one internal tree IT. That is, the workers may perform a work for the at least one internal tree IT. The first work may be divided several times and assigned to the global shared work queue.

Each of the workers may perform the work in a work stealing queue of each of the workers. A worker which has completed one work may steal other work to perform the other work. Accordingly, the workers may perform the work efficiently. At this time, when at least two workers attempt to steal a same work at a same time, a race condition may occur. To prevent this, an operation of stealing the work may be performed by a method in which a critical zone is designated based on a semaphore or a mutex, or by a method in which the work stealing queue is implemented as a thread-safe or lock-free data structure.

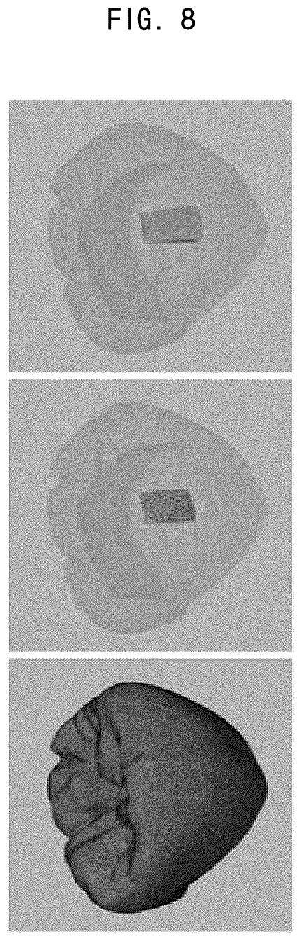

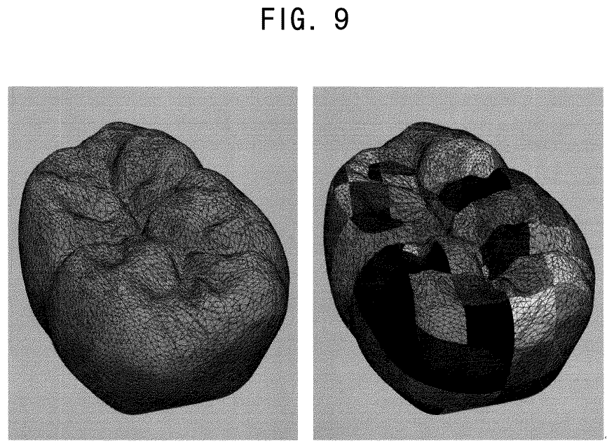

FIG. 8 and FIG. 9 are diagrams illustrating a dental object on which a method of representing a dental object using a binary space partitioning according to an embodiment of the present inventive concept is performed.

Referring to FIG. 8, a space may include an object including a polygon mesh. The space may be a three-dimensional space, the polygon mesh may be triangles, and a shape of the object may be a dental object. For example, the dental object may be a tooth.

A left diagram shows a space generated based on the dental object and internal trees IT. A center diagram shows a part of a dental object included in the space generated based on the internal trees IT. A right diagram shows a part of a dental object represented based on a leaf tree LT.

Referring to FIG. 9, a left diagram shows a dental object in which a method of representing a dental object using a binary space partitioning according to an embodiment of the present inventive concept is not performed. A right diagram shows a dental object in which a method of representing a dental object using a binary space partitioning according to an embodiment of the present inventive concept is performed.

Conventional binary space partitioning is not efficiently parallelized, such that the conventional binary space partitioning is inappropriate for complex data such as a dental object or an arch mesh model. As shown in FIGS. 8 and 9, a method of representing a dental object using binary space partitioning according to an embodiment of the present inventive concept may be efficiently parallelized even for the complex data.

As such, according to a method of representing a dental object using a binary space partitioning according to an embodiment of the present inventive concept, a space including a dental object including a polygon mesh may uniformly include a number of polygon meshes included in each of spaces generated based on internal trees IT by the internal trees IT. Therefore, since an operation performed in each of the spaces generated based on the internal trees IT may be uniformly performed, the operation may be efficiently parallelized and less memory space may be required.

In addition, the internal trees IT may be generated by a working stealing algorithm. Therefore, workers may efficiently perform a work.

The method of representing the dental object using the binary space partitioning according to an embodiment of the present inventive concept enables a fast and precise three-dimensional geometric operation, and may be applied to various fields such as CAD/CAM (Computer-Aided Design/Computer-Aided Manufacturing software), virtual and augmented reality, and 3D printing.

Meanwhile, the method of representing the dental object using the binary space partitioning according to an embodiment of the present inventive concept may not be limited to the dental object. For example, the method of representing the dental object using the binary space partitioning according to an embodiment of the present inventive concept may be applied to objects other than the dental object. Therefore, the method of representing the dental object using the binary space partitioning according to an embodiment of the present inventive concept may be substantially equal to an configuration and an operation as the method of representing an object using a binary space partitioning according to an embodiment of the present inventive concept.

According to an embodiment of the present inventive concept, a non-transitory computer-readable storage medium having stored thereon program instructions of the method of representing the dental object using the binary space partitioning according to an embodiment of the present inventive concept and the method of representing the object using the binary space partitioning according to an embodiment of the present inventive concept may be provided. The above mentioned method may be written as a program executed on the computer. The method may be implemented in a general purpose digital computer which operates the program using a computer-readable medium. In addition, the structure of the data used in the above mentioned method may be written on a computer readable medium through various means. The computer readable medium may include program instructions, data files and data structures alone or in combination. The program instructions written on the medium may be specially designed and configured for the present inventive concept, or may be generally known to a person skilled in the computer software field. For example, the computer readable medium may include a magnetic medium such as a hard disk, a floppy disk and a magnetic tape, an optical recording medium such as CD-ROM and DVD, a magneto-optical medium such as floptic disc and a hardware device specially configured to store and execute the program instructions such as ROM, RAM and a flash memory. For example, the program instructions may include a machine language codes produced by a compiler and high-level language codes which may be executed by a computer using an interpreter or the like. The hardware device may be configured to operate as one or more software modules to perform the operations of the present inventive concept.

In addition, the above mentioned method of representing the dental object using the binary space partitioning and the above mentioned method of representing the object using the binary space partitioning may be implemented in a form of a computer-executed computer program or an application which are stored in a storage method.

The present inventive concept relates to the method of representing the dental object using the binary space partitioning, the method of representing the object using the binary space partitioning, and a computer-readable medium having the program for executing the same, which may reduce an effort and a time for a arithmetic operation and improve an accuracy and an productivity.

The foregoing is illustrative of the present inventive concept and is not to be construed as limiting thereof. Although a few embodiments of the present inventive concept have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the appended claims. The present inventive concept is defined by the following claims, with equivalents of the claims to be included therein.

What is claimed is:

1. A method of representing a dental object using binary space partitioning, the method comprising:
generating internal trees for partitioning a space including the dental object represented as a polygon mesh; and
generating leaf trees for representing a shape of the dental object in spaces generated based on the internal trees,
wherein each of the internal trees and the leaf trees includes internal nodes and leaf nodes.

2. The method of claim 1, wherein when the space is partitioned, a median splitting technique is performed such that a number of faces of the polygon mesh is halved.

3. The method of claim 1, wherein the internal trees constitute first to N-th (wherein N is a natural number greater than or equal to 1) internal tree layers, and internal trees included in the second internal tree layer are constituted based on leaf nodes of an internal tree included in the first internal tree layer.

4. The method of claim 3, wherein a depth of nodes included in each of the internal trees is less than or equal to a maximum partial tree depth.

5. The method of claim 3, wherein the leaf trees constitute one leaf tree layer.

6. The method of claim 5, wherein the leaf trees are constituted based on the leaf nodes of internal trees included in the N-th internal tree layer.

7. The method of claim 1, wherein a depth of the nodes included in the internal trees and the leaf trees is less than or equal to a maximum augmented tree depth.

8. The method of claim 1, wherein a number of polygon meshes included in each of the spaces generated based on the internal trees is less than or equal to a maximum number of leaf tree space faces.

9. The method of claim 1, wherein parent nodes and child nodes are constituted based on the internal nodes and the leaf nodes, and each of the parent nodes has two child nodes.

10. The method of claim 1, wherein the internal trees and the leaf trees constitute parent trees and child trees, and each of the parent trees has at least two child trees.

11. The method of claim 1, wherein the internal trees are generated by a working stealing algorithm.

12. The method of claim 11, wherein the working stealing algorithm is performed by workers, and the workers perform a work on at least one internal tree.

13. The method of claim 12, wherein each of the workers is configured to perform the work in a working stealing queue of each of the workers, and a worker which has completed one work is configured to steal other work to perform the other work.

14. The method of claim 1, wherein the polygon mesh is a polygonal face.

15. The method of claim 1, wherein when the space is two-dimensional, the space is partitioned by a first-dimensional straight line.

16. The method of claim 1, wherein when the space is three-dimensional, the space is partitioned by a two-dimensional plane.

17. A method of representing an object using binary space partitioning, the method comprising:
generating internal trees for partitioning a space including the object represented as a polygon mesh; and
generating leaf trees for representing a shape of the object in spaces generated based on the internal trees,
wherein each of the internal trees and the leaf trees includes internal nodes and leaf nodes.

18. The method of claim 17, wherein a depth of nodes included in each of the internal trees is less than or equal to a maximum partial tree depth.

19. The method of claim 17, wherein a number of polygon meshes included in each of the spaces generated based on the internal trees is less than or equal to a maximum number of leaf tree space faces.

20. A non-transitory computer-readable storage medium having stored thereon program instructions, the program instructions executable by at least one hardware processor to:
generate internal trees for partitioning a space including the dental object represented as a polygon mesh; and
generate leaf trees for representing a shape of the dental object in spaces generated based on the internal trees,
wherein each of the internal trees and the leaf trees includes internal nodes and leaf nodes.
